(19) United States
(12) Patent Application Publication
(10) Pub. No.: US 2006/0097769 A1
(43) Pub. Date: May 11, 2006

(54) Level shift circuit and semiconductor circuit device including the level shift circuit

(75) Inventors: Yukihiro Mizukami, Ibaraki-shi (JP); Kazuhisa Raita, Kyoto-shi (JP)

Correspondence Address: STEPTOE & JOHNSON LLP, 1330 CONNECTICUT AVE., NW, WASHINGTON, DC, 20036, US

(73) Assignee: Matsushita Electric Industrial Co., LTD., Kadoma-shi (JP)

(21) Appl. No.: 11/261,593

(22) Filed: Oct. 31, 2005

(30) Foreign Application Priority Data
Nov. 5, 2004 (JP) 2004-321374

(51) Int. Cl. H03L 5/00

(52) U.S. Cl. 327/333

(57) ABSTRACT

In a level shift circuit constituted by n-channel MOS transistors (TN-A and TN-B) and p-channel MOS transistors (TP-A and TP-B), p-channel MOS transistors (TP-C and TP-D) constituting a current mirror circuit at the transistors (TP-A and TP-B), thereby limiting a direct tunneling current from VDDH to VSS and enabling high-speed operation.

### FIELD OF THE INVENTION

The present invention relates to a level shift circuit which converts a signal of a low-power-supply-voltage amplitude signal into a high-power-supply-voltage amplitude signal in a semiconductor integrated circuit requiring a plurality of power supply voltages, and to a semiconductor integrated circuit device including the level shift circuit.

### BACKGROUND OF THE INVENTION

A conventional level shift circuit (see, for example, Japanese Patent Laid-Open No. 2001-257581) can be operated comparatively easily if the voltage amplitude is small or if the operating speed is not high. However, the difficulty in normally operating the circuit due to an increase in direct tunneling current or the like is increased if the voltage amplitude is larger or if the operating speed is higher. Contrivances to solve this problem, e.g., one in which a circuit for controlling a current is added to a level shift circuit (see, for example, Japanese Patent Laid-Open No. 2002-118458) are known.

FIG. 15 shows a conventional level shift circuit widely used.

The circuit shown in FIG. 15 will be described by assuming that p-channel MOS transistors connected to a first power supply voltage VDD are TP1 and TP2; n-channel MOS transistors connected to a second power supply voltage VSS are TN1 and TN2; p-channel MOS transistors connected to a third power supply voltage VDDH higher than the first power supply voltage VDD are TP-A and TP-B; and n-channel MOS transistors connected to the second power supply voltage VSS are TN-A and TN-B.

The transistors TP1 and TN1 are connected together in an inverter configuration. The transistors TP2 and TN2 are also connected in an inverter configuration.

A signal having an amplitude between the first power supply voltage VDD and the second power supply voltage VSS is input as an input signal IN. The transistors TP1 and TN1 receive this signal through their gates, and the transistors TP2 and TN2 receive through their gates an inverter output J1 in phase opposition to the input signal IN to generate an inverter output J2 in phase with the input signal IN.

This inverter output J2 is applied to the gate of the transistor TN-A. The source of the transistor TN-A is connected to the second power supply voltage VSS, and the drain of the transistor TN-A is connected to the drain of the transistor TP-A. The source of the transistor TP-A is connected to the third power supply voltage VDDH.

The inverter output J1 is applied to the gate of the transistor TN-B. The source of the transistor TN-B is connected to the second power supply voltage VSS, and the drain of the transistor TN-B is connected to the drain of the transistor TP-B. The source of the transistor TP-B is connected to the third power supply voltage VDDH.

The gate of the transistor TP-A is connected to the drain of the transistor TN-B, and the gate of the transistor TP-B is connected to the drain of the transistor TN-A. An output signal OUT is output from a point of connection between the drain of the transistor TP-B and the drain of the transistor TN-B.

The basic operation of the conventional level shift circuit shown in FIG. 15 will now be described.

When the voltage of the input signal IN changes from a “Low” level equal to the second power supply voltage VSS to a “high” level equal to the first power supply voltage VDD in a state where the input signal IN is fixed and where the voltages on wiring lines are stable, the gate of the transistor TN-A is turned on. The gates of the two transistors TN-A and TP-A are on during a short time period from the moment at which the input signal IN changes as described above to the moment at which the transistor TP-B is turned on. During this time period, a direct tunneling current flows from the third power supply voltage VDDH to the second power supply voltage VSS.

This direct tunneling current also influences the voltage on the wiring connecting the drain of the transistor TN-A and the gate of the transistor TP-B. During a time period before the gate of the transistor TP-B is stabilized at the “Low” level, therefore, the direct tunneling current flows and influences the delay time.

When the gate of the transistor TP-B is turned on, there is a need to set the gate of the transistor TP-A to a “High” level equal to the third power supply voltage VDDH in order to stabilize the voltage of the output signal OUT at the “High” level. To do so, cutting of the route from the third power supply voltage VDDH to the second power supply voltage VSS passing through the sources and the drains of the two transistors TN-A and TP-A is required. The gate of the transistor TP-A and the output signal OUT are changed from the “Low” level to the “High” level. A current therefore flows between the source and the drain of the transistor TP-A.

As described above, a direct tunneling current flows through the transistor TN-A and the transistor TP-A at an initial stage of change in voltage from “Low” level to “High” level. Also at a final stage of change in voltage from “Low” to “High”, a current also flows from the third power supply voltage VDDH to the second power supply voltage VSS via the transistors TP-A and TN-A.

In the conventional circuit shown in FIG. 15, the value at the output terminal is not fixed before the gates of the transistors TP-B and TP-A are turned on and off, respectively, after the gates of the transistors TN-A and TP-B have been turned on and off, respectively. Also, in a case where the third power supply voltage VDDH is much higher than the first power supply voltage VDD or in a case where the operating frequency is high, it is important to consider how to limit the direct tunneling current in order to complete the above-described operating steps with a reduced delay time.

The operation when the input signal IN is changed from “High” to “Low” will also be considered.

First, the positive and negative logic values of the input signals IN are supplied to the gates of the transistors TN-A and TN-B, respectively. Second, the wiring connecting the drain of the transistor TP-A and the drain of the transistor TN-A can be regarded as a terminal for output of the negative logic value of the output signal OUT when the input signal IN is stable, since the wiring connecting the drain of the transistor TP-A and the grain of the transistor TN-A always has a value which is the inverse of that of the wiring connecting the drain of the transistor TP-B and the drain of the transistor TN-B. From these two points, the operation at the time of change from “High” to “Low” can also be understood in the same way as the above-described operation at the time of change from “Low” to “High”, since the circuit shown in FIG. 15 has a bilateral symmetric structure.

An object of the present invention is to provide a level shift circuit capable of operating at a high speed while limiting the power consumption by suppressing the direct tunneling current from the third power supply voltage VDDH to the second power supply voltage VSS and a semiconductor integrated circuit device including the level shift circuit.

### DISCLOSURE OF THE INVENTION

According to the first aspect of the present invention, a level shift circuit in which an input signal having a first voltage difference is converted into an output signal having a second voltage difference larger than the first voltage difference, includes a first MOS transistor having a first type of conductivity, the input signal being supplied to the gate of the first MOS transistor, a low-voltage-side reference voltage of the output signal being supplied to the source of the first MOS transistor, a second MOS transistor having the first type of conductivity, an inverted signal obtained by inverting the input signal being supplied to the gate of the second MOS transistor, the low-voltage-side reference voltage being supplied to the source of the second MOS transistor, a third MOS transistor having a second type of conductivity, having its drain connected to the drain of the first MOS transistor and having its gate connected to the drain of the second MOS transistor, a fourth MOS transistor having the second type of conductivity, having its drain connected to the drain of the second MOS transistor and having its gate connected to the drain of the first MOS transistor, and a fifth MOS transistor and a sixth MOS transistor provided between the sources of the third and fourth MOS transistors and nodes to which a high-voltage-side reference voltage having the second voltage difference from the low-voltage-side reference voltage is supplied, the fifth and sixth MOS transistors constituting a current mirror circuit, each of the fifth and sixth MOS transistors having the second type of conductivity, wherein the output signal is output from a point of connection between the drain of the second MOS transistor and the drain of the fourth MOS transistor.

A level shift circuit according to the second aspect of the present invention is such that in the level shift circuit according to the first aspect, the gate of the fifth MOS transistor and the gate of the sixth MOS transistor are connected to the drain of the sixth MOS transistor.

A level shift circuit according to the third aspect of the present invention is such that in the level shift circuit according to the first aspect, the gate of the fifth MOS transistor and the gate of the sixth MOS transistor are connected to the drain of the fifth MOS transistor.

A level shift circuit according to the fourth aspect of the present invention is such that in the level shift circuit according to the second aspect, a voltage equal to a voltage on a point of connection between the third MOS transistor and the fifth MOS transistor is supplied to the substrate of the third MOS transistor, and a voltage equal to a voltage on a point of connection between the fourth MOS transistor and the sixth MOS transistor is supplied to the substrate of the fourth MOS transistor.

A level shift circuit according to the fifth aspect of the present invention is such that in the level shift circuit according to the third aspect, a voltage equal to a voltage on a point of connection between the third MOS transistor and the fifth MOS transistor is supplied to the substrate of the third MOS transistor, and a voltage equal to a voltage on a point of connection between the fourth MOS transistor and the sixth MOS transistor is supplied to the substrate of the fourth MOS transistor.

A level shift circuit according to the sixth aspect of the present invention is such that in the level shift circuit according to the second aspect, the substrate voltage of the third MOS transistor is equal to the substrate voltage of the fifth MOS transistor, and the substrate voltage of the fourth MOS transistor is equal to the substrate voltage of the sixth MOS transistor.

A level shift circuit according to the seventh aspect of the present invention is such that in the level shift circuit according to the third aspect, the substrate voltage of the third MOS transistor is equal to the substrate voltage of the fifth MOS transistor, and the substrate voltage of the fourth MOS transistor is equal to the substrate voltage of the sixth MOS transistor.

According to the eighth aspect of the present invention, a level shift circuit in which an input signal having a first voltage difference is converted into an output signal having a second voltage difference larger than the first voltage difference, includes a first MOS transistor having a first type of conductivity, the input signal being supplied to the gate of the first MOS transistor, a low-voltage-side reference voltage of the output signal being supplied to the source of the first MOS transistor, a second MOS transistor having the first type of conductivity, an inverted signal obtained by inverting the input signal being supplied to the gate of the second MOS transistor, the low-voltage-side reference voltage being supplied to the source of the second MOS transistor, a third MOS transistor having a second type of conductivity, having its drain connected to the drain of the first MOS transistor and having its gate connected to the drain of the second MOS transistor, a fourth MOS transistor having the second type of conductivity, having its drain connected to the drain of the second MOS transistor and having its gate connected to the drain of the first MOS transistor, a plurality of current mirror circuits provided between the sources of the third and fourth MOS transistors and nodes to which a high-voltage-side reference voltage having the second voltage difference from the low-voltage-side reference voltage is supplied, and a selector which selects, according to a control input, one of the plurality of current mirror circuits to have effective connections to the sources of the third and fourth MOS transistors, wherein the output signal is output from a point of connection between the drain of the second MOS transistor and the drain of the fourth MOS transistor.

A level shift circuit according to the ninth aspect of the present invention is such that in the level shift circuit according to the eighth aspect, each of the plurality of current mirror circuits includes fifth and sixth MOS transistors having the second type of conductivity, the gate of the fifth MOS transistor and the gate of the sixth MOS transistor being connected to the drain of the fifth MOS transistor or the drain of the sixth MOS transistor.

A level shift circuit according to the tenth aspect of the present invention is such that in the level shift circuit according to the ninth aspect, the circuit further includes pairs of seventh and eighth MOS transistors provided between the plurality of current mirror circuits and the sources of the third and fourth MOS transistors, the gates of each pair of seventh and eight MOS transistors being connected to each other, each of the seventh and eight MOS transistors having the second type of conductivity. In this level shift circuit, a selecting circuit selects according to the control input one of the plurality of current mirror circuits to be used by outputting, to a node to which the gates of the seventh and eight MOS transistors are connected in common, a selecting signal by which the corresponding seventh and eight MOS transistors are made conductive.

According to the eleventh aspect of the present invention, a level shift circuit in which an input signal having a first voltage difference is converted into an output signal having a second voltage difference larger than the first voltage difference, includes a first MOS transistor having a first type of conductivity, the input signal being supplied to the gate of the first MOS transistor, a low-voltage-side reference voltage of the output signal being supplied to the source of the first MOS transistor, a second MOS transistor having the first type of conductivity, an inverted signal obtained by inverting the input signal being supplied to the gate of the second MOS transistor, the low-voltage-side reference voltage being supplied to the source of the second MOS transistor, a third MOS transistor having a second type of conductivity, having its drain connected to the drain of the first MOS transistor and having its gate connected to the drain of the second MOS transistor, a fourth MOS transistor having the second type of conductivity, having its drain connected to the drain of the second MOS transistor and having its gate connected to the drain of the first MOS transistor, fifth and sixth MOS transistors provided between the sources of the third and fourth MOS transistors and nodes to which a high-voltage-side reference voltage having the second voltage difference from the low-voltage-side reference voltage is supplied, the fifth and sixth MOS transistors constituting a current mirror circuit, each of the fifth and sixth MOS transistors having the second type of conductivity, a first switch circuit which establishes or cancels a connection between the drain of the fifth MOS transistor and a point of connection between the gate of the fifth MOS transistor and the gate of the sixth MOS transistor, a second switch circuit which establishes or cancels a connection between the drain of the sixth MOS transistor and a point of connection between the gate of the fifth MOS transistor and the gate of the sixth MOS transistor, and a selecting circuit which selects according to a control input one of the first switch circuit and the second switch circuit so that the first or second switch circuit is set in a connecting state, wherein the output signal is output from a point of connection between the drain of the second MOS transistor and the drain of the fourth MOS transistor.

A level shift circuit according to the twelfth aspect of the present invention is such that in the level shift circuit according to the first aspect, the first type of conductivity is the n-channel type while the second type of conductivity is the p-channel type.

A level shift circuit according to the thirteenth aspect of the present invention is such that in the level shift circuit according to the eighth aspect, the first type of conductivity is the n-channel type while the second type of conductivity is the p-channel type.

A level shift circuit according to the fourteenth aspect of the present invention is such that in the level shift circuit according to the eleventh aspect, the first type of conductivity is the n-channel type while the second type of conductivity is the p-channel type.

According to the fifteenth aspect of the present invention, a semiconductor integrated circuit device is mounted with the level shift circuit according to the eighth aspect.

A semiconductor integrated circuit device according to the sixteenth aspect of the present invention is such that in the semiconductor integrated circuit device according to the fifteenth aspect, selection of one of the plurality of current mirror circuits by the selector is performed according to a control input designated through an external terminal.

A semiconductor integrated circuit device according to the seventeenth aspect of the present invention is such that in the semiconductor integrated circuit device according to the fifteenth aspect, the selector includes an information storage constituted by a memory or a register, and a selecting circuit which selects, according to an output from the information storage, one of the plurality of current mirror circuits to be used.

A semiconductor integrated circuit device according to the eighteenth aspect of the present invention is such that in the semiconductor integrated circuit device according to the seventeenth aspect, the information storage includes a non-rewritable nonvolatile memory.

A semiconductor integrated circuit device according to the nineteenth aspect of the present invention is such that in the semiconductor integrated circuit device according to the seventeenth aspect, the information storage includes a rewritable nonvolatile memory.

A semiconductor integrated circuit device according to the twentieth aspect of the present invention is such that in the semiconductor integrated circuit device according to the nineteenth aspect, information in the rewritable nonvolatile memory is stored in an ordinary program storage region in the rewritable nonvolatile memory.

A semiconductor integrated circuit device according to the twenty-first aspect of the present invention is such that in the semiconductor integrated circuit device according to the nineteenth aspect, information in the rewritable nonvolatile memory is stored in a redundant storage region in the rewritable nonvolatile memory.

A semiconductor integrated circuit device according to the twenty-second aspect of the present invention is such that in the semiconductor integrated circuit device according to the nineteenth aspect, information in the rewritable nonvolatile memory is stored in an ID code setting region in the rewritable nonvolatile memory.

A semiconductor integrated circuit device according to the twenty-third aspect of the present invention is such that in the semiconductor integrated circuit device according to the nineteenth aspect, information in the rewritable nonvolatile memory is stored in a testing storage region in the rewritable nonvolatile memory.

The level shift circuit and the semiconductor integrated circuit device including the level shift circuit are capable of reducing the power consumption and increasing the operating speed by adding several transistors in comparison with the conventional level shift circuit.

### BRIEF DESCRIPTION OF THE DRAWINGS

FIG. 1 is a diagram showing a configuration of a level shift circuit according to Embodiment 1 of the present invention;

FIG. 2 is a diagram showing a configuration of a level shift circuit according to Embodiment 2 of the present invention;

FIG. 3 is a diagram showing a configuration of a level shift circuit according to Embodiment 3 of the present invention;

FIG. 4 is a diagram showing a configuration of a level shift circuit according to Embodiment 4 of the present invention;

FIG. 5 is a graph showing voltage and current with respect to time at a drain of transistor TP-C at an instant when the value of input signal IN changes from “Low” to “High” in the level shift circuit according to Embodiment 1;

FIG. 6 is a graph showing voltage and current with respect to time at a drain of transistor TP-D at an instant when the value of input signal IN changes from “Low” to “High” in the level shift circuit according to Embodiment 1;

FIG. 7 is a graph showing voltage and current with respect to time at a drain of transistor TP-C at an instant when the value of input signal IN changes from “Low” to “High” in the level shift circuit according to Embodiment 2;

FIG. 8 is a graph showing voltage and current with respect to time at a drain of transistor TP-D at an instant when the value of input signal IN changes from “Low” to “High” in the level shift circuit according to Embodiment 2;

FIG. 9 is a sectional view of transistors TN-A, TP-A, and TP-C in a case where the level shift circuit shown in FIG. 1 is implemented on a p-channel-type semiconductor substrate;

FIG. 10 is a sectional view of transistors TN-A, TP-A, and TP-C in a case where the level shift circuit shown in FIG. 3 is implemented on a p-channel-type semiconductor substrate;

FIG. 11 is a diagram showing a configuration of a level shift circuit according to Embodiment 5 of the present invention;

FIG. 12 is a diagram showing a configuration of a level shift circuit according to Embodiment 6 of the present invention;

FIG. 13 is a diagram showing a configuration of a level shift circuit according to Embodiment 7 of the present invention;

FIG. 14 is a diagram showing a configuration of a level shift circuit according to Embodiment 8 of the present invention; and

FIG. 15 is a diagram showing a configuration of a conventional level shift circuit.

### DESCRIPTION OF THE EMBODIMENTS

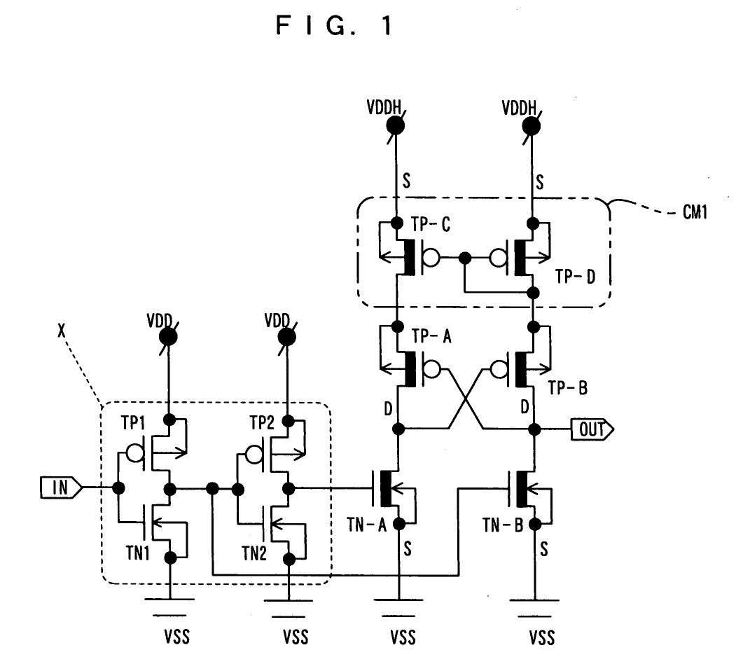

Embodiments of the present invention will be described with reference to FIGS. 1 to 14.

### Embodiment 1

FIGS. 1, 5, 6, and 9 show a level shift circuit (Embodiment 1) of the present invention.

Referring to FIG. 1 which is a circuit diagram of the level shift circuit (Embodiment 1), the positive and negative logic values of an input signal IN are respectively supplied to the gate of a first MOS transistor TN-A and the gate of a second MOS transistor TN-B through an inverter circuit X in a low-voltage operation region. Each of the transistors TN-A and TN-B is of the n-channel conduction type and has its substrate voltage and source connected to a second power supply voltage VSS.

The inverter circuit X has p-channel MOS transistors TP1 and TP2 connected to a first power supply voltage VDD and n-channel MOS transistors TN1 and TN2 connected to the second power supply voltage VSS, as does the corresponding circuit shown in FIG. 15. The transistors TP1 and TN1 constitute an inverter. The transistors TP1 and TN2 also constitute an inverter.

The drain of the transistor TN-A is connected to the drain of a third MOS transistor TP-A. The drain of the transistor TN-B is connected to the drain of a fourth MOS transistor TP-B. Each of the transistors TP-A and TP-B is of the p-channel conduction type and has its substrate voltage connected to its source.

The gate of the transistor TP-B is connected to the drain of the transistor TN-A, and the gate of the transistor TP-A is connected to the drain of the transistor TN-B.

The sources of the transistors TP-A and TP-B are connected to a third power supply voltage VDDH through a current mirror circuit CM1 formed by a fifth MOS transistor TP-C and a sixth MOS transistor TP-D. Each of the transistors TP-C and TP-D is of the p-channel conduction type and has its substrate voltage connected to its source. More specifically, the source and the substrate voltage of the transistor TP-A are connected to the drain of the transistor TP-C to make the substantial voltage on the source of the transistor TP-A dependent on the current mirror circuit formed by the transistors TP-C and TP-D. Similarly, the source and substrate voltage of the transistor TP-B are connected to the drain of the transistor TP-D. Also, the gates of the transistors TP-C and TP-D are connected to the drain of the transistor TP-D to mirror the current flowing from the source to the drain of the transistor TP-D in the source-drain current of the transistor TP-C. An output signal OUT is taken out from a point of connection between the drain of the transistor TN-B and the drain of the transistor TP-B.

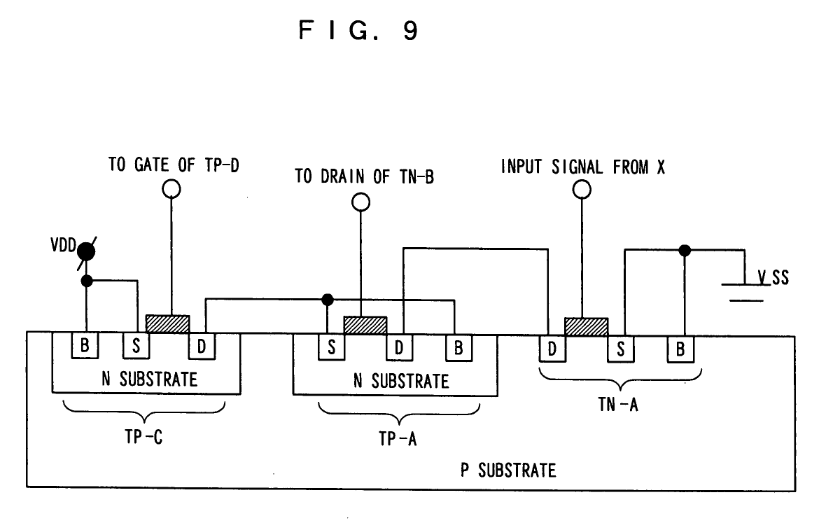

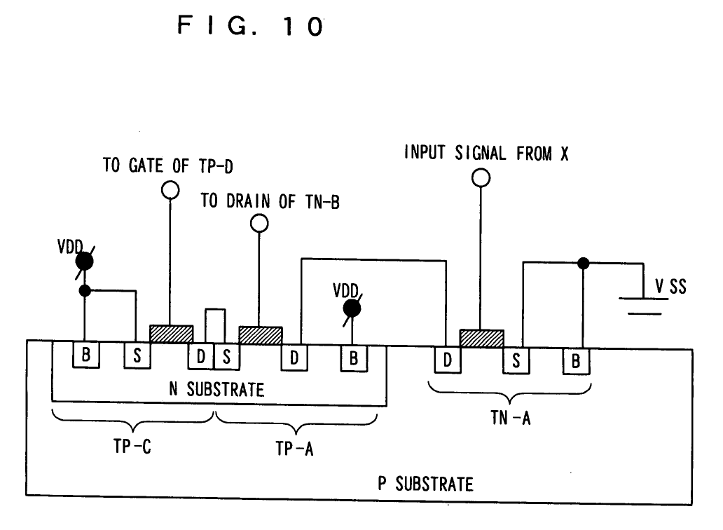

FIG. 9 is a sectional view of the transistors TN-A, TP-A, and TP-C in the case of implementation of the circuit on a p-channel semiconductor.

In the level shift circuit shown in FIG. 1, the arrangement for solving the problem of the conventional art includes the current mirror circuit CM1 formed by the transistor TP-C and the transistor TP-D is provided as a voltage source on the VDDH side (high-voltage-side reference voltage), and the substrate voltages of the transistors TP-A and TP-B are set in common with the sources of these transistors to substantially reduce the source voltages of the transistors TP-A and TP-B only at the instant when the level shift circuit operates from “High” to “Low” or from “Low” to “High”, thus facilitating the on/off operation of the transistors TP-A and TP-B. A direct tunneling current can be limited by this effect to reduce the delay.

A p-channel transistor having its gate and drain connected together, as in the case of the transistor TP-D shown in FIG. 1, operates in a single state as described below. The drain of the transistor TP-D operates in a saturated region at all times and, therefore, the voltage on the drain is equal to VDDH and is stable in the state where the source-drain voltage difference is zero. When a current is caused to flow between the source and the drain, a voltage difference is produced between the source and the drain. At this time, since the transistors TP-C and TP-D have the gate connection point in common with each other, the amount of current which can be caused to flow between the source and the drain of the transistor TP-D is the same as that in the transistor TP-C.

Accordingly, when a direct tunneling current flows from VDDH to VSS via the transistors TN-A, TP-A, and TP-C in the circuit shown in FIG. 1, a voltage is generated by the current flowing between the source and the drain of the transistor TP-C. As a result, the voltage on the drain of the transistor TP-C has a value determined by dividing VDDH, and the voltage on the source of the transistor TP-A is thereby reduced temporarily. At this time, the direct tunneling current itself is also limited by the current mirror circuit CM1 to enable the transistors TP-A and TP-B to operate on/off at a higher speed.

The operation will be described more concretely.

An example of the operation in which a low-voltage amplitude between 0 volt and 1.8 volts (=VDD) applied as input signal IN is transmitted as a high-voltage amplitude between 0 volt and 5 volts (=VDDH) to be obtained as output signal OUT will be described.

A state in which the input signal IN is stable at 0-volt “Low” will first be considered. In this state, the gate of the transistor TN-A is in the off state and the gate of the transistor TN-B is in the on state. Accordingly, 0-volt “Low” is output as the output signal OUT. At this time, the gate of the transistor TP-A is in the on state and the gate of the transistor TP-B is in the off state. In this state, therefore, no direct tunneling current from 5 volts to 0 volt flows. The operation of the transistors TP-C and TP-D is maintained in a stable condition in a saturated region since no currents flow through the transistors TP-A and TP-B to which the drains of the transistors TP-C and TP-D are connected. A voltage of 5 volts appears on the sources and drains of the transistors TP-C and TP-D. Since the voltages on the sources and drains of the transistors TP-C and TP-D are equal to each other, the voltage between 0 volt and 5 volts is not divided by the transistors TP-C and TP-D, and the voltages on the sources of the transistors TP-A and TP-B are 5 volts.

A state immediately after change of the input signal IN from “Low” level to 1.8-volt “High” level will next be considered.

Through the inverter circuit X in the low-voltage operation region, 1.8-volt “High” level and 0-volt “Low” level of the input signal IN are applied to the gate of the transistor TN-A and the gate of the transistor TN-B, respectively. At this time, the gate of the transistor TP-A is in the on state while the gate of the transistor TP-B is in the off state. At this instant, the gates of the transistors TN-A and TP-A are still in the on state and the section from the source of the transistor TN-A at 0 volt to the source of the transistor TP-C at 5 volts is in the on state, so that a direct tunneling current flows.

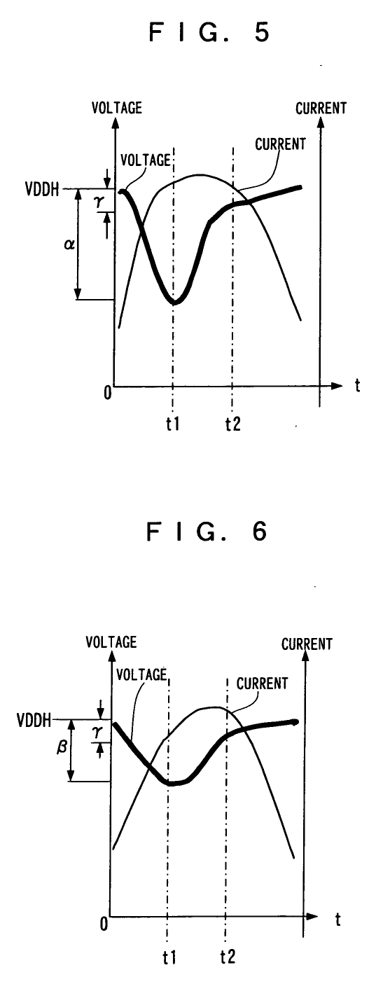

FIG. 5 shows variations in voltage and current with respect to time at the drain of the transistor TP-C at the instant when the value of the input signal IN changes from “Low” to “High”.

This instant is shown as t1. The transistors TP-C and TP-D operate in the saturated region at all times and a current is thereby caused to flow between the source and the drain of the transistor TP-C. However, since the direct tunneling current flowing through the transistors TP-C, TP-A, and TN-A exceeds the amount of current caused by the current mirror effect, a voltage α is generated between the source and the drain, and the voltage on the wiring connecting the drain of the transistor TP-C and the source of the transistor TP-A is reduced to a value “VDDH-α”. The state of the gate of the transistor TP-A is thereby made variable. Also, the amount of current flowing between the source and the drain of the transistor TP-C is limited by the current mirror effect characterized by dependence of the voltage on the transistor TP-C on the state of the transistor TP-D.

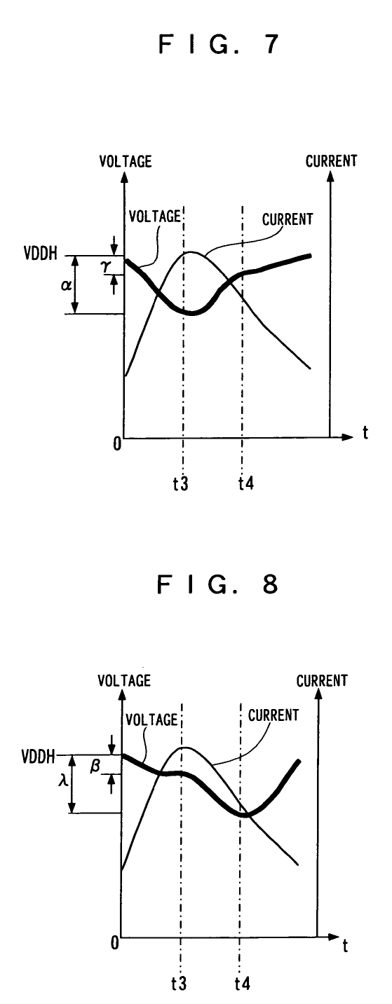

FIG. 6 shows variations in voltage and current with respect to time at the drain of the transistor TP-D.

The corresponding instance on time axis in FIG. 6 is the same as that in FIG. 5 and is therefore shown as t1. The gate of the transistor TP-B has changed to the “Low” state since it is also connected to the drain of the transistor TN-A. Accordingly, the value of the current flowing from the source of the transistor TP-D and passing through the drain of the transistor TP-B is proportional to the state of the gate of the transistor TP-B.

If the voltage difference produced between the source and the drain of the transistor TP-D is A, the voltage on the drain is “VDDH-β”, and the voltage on the gate of the transistor TP-D is also “VDDH-β” since this gate is connected to the gate of the transistor TP-C. The voltage on the gate of the transistor TP-C is also the same.

The current flowing between the source and the drain of the transistor TP-C and the current flowing between the source and the drain of the transistor TP-D are as described below. The value of the current between the source and the drain of the transistor TP-D is directly reflected in the value of the current between the source and the drain of the transistor TP-C since the voltages on the gates are equal to each other because of the operation of the current mirror circuit CM1 formed by the transistors TP-C and TP-D. However, if the voltage difference between the source and the drain of the transistor TP-C is β, a relationship “α>β” is established because the value of the current flowing between the source and the drain of the transistor TP-C exceeds the value of the current reflected from the transistor TP-D.

Consequently, the source voltage is 5 volts and the drain voltage is “5 volts-α” in the transistor TP-C at the instant t1 immediately after the transition of the value of the input signal IN from “Low” to “High”, and the source voltage is 5 volts and the drain voltage is “5 volts-β” in the transistor TP-D at this instant, as shown in FIGS. 5 and 6. The amount of current flowing between the source and the drain of the transistor TP-C at this time exceeds the amount of current flowing by the current mirror effect. Therefore, the direct tunneling current is larger than the current flowing between the source and the drain of the transistor TP-D, although the maximum of the direct tunneling current itself is limited.

The above-described operation will be considered from the transistor TP-A/TP-B side. In the transistor TP-A, at the time of transition from the on state to the off state, the source voltage decreases from 5 volts to “5 volts-α” and the gate voltage changes gradually to “5 volts-β” under the influence of the drain voltage of the transistor TP-B. Simultaneously, in the transistor TP-B, at the time of transition from the off state to the on state, the source voltage decreases from 5 volts to “5 volts-β” and the gate voltage changes to 0 volt. At this point in time, therefore, the transistor TP-B is substantially in the on state.

The operation from the state in which both the transistors TP-A and TP-B are in the on state to settlement of a 5-volt “High” output obtained as the output signal OUT will next be considered.

The values of the current and voltage at the drains of the transistors TP-C and TP-D at this instant correspond to the states at time t2 shown in FIGS. 5 and 6. Since the drain of the transistor TP-B is connected to the output signal OUT and to the gate of the transistor TP-A, a current flows between the source and the drain when the transistor TP-B becomes completely on. The value of this current is smaller than the values of the currents flowing as source-drain currents in the transistors TP-D and TP-C immediately after change of the input signal IN, since the gate of the transistor TP-B is substantially in the low-level state. Consequently, the voltage difference produced between the source and the drain of the transistor TP-D is smaller than β. This voltage difference is hereinafter referred to as γ (α>β>γ).

The current value becomes greater in proportion to the voltage difference γ between the source and the drain of the transistor TP-D. However, the gate of the transistor TP-B is substantially in the “Low” state at this point in time. Therefore, after the current value has been temporarily increased to turn off the gate of the transistor TP-A, the gate of the transistor TP-A and the output signal OUT become “High”.

On the other hand, in the transistor TP-A, the voltage on the drain of the transistor TP-A becomes “Low” when the voltage on the gate of the transistor TP-B connected by the common wiring becomes substantially “Low”. At this stage, a current flows between the source and the drain of the transistor TP-A but the gate is in the “High” state. Also, the values of the currents flowing as source-drain currents in the transistors TP-A and TP-C are not large since the current value of the transistor TP-D is reflected by the current mirror effect. Voltage differences are also generated in the same way. Accordingly, the drain voltages of the transistors TP-C and TP-D decrease to the maximum value “VDDH-γ” when currents flow, and thereafter recover to VDDH in proportion to the reduction in current value.

The above-described operation will be considered from the transistor TP-A/TP-B side. The transistor TP-B is stable in the on state and, therefore, a current flows between the source and the drain before transition of the output signal OUT and the gate of the transistor TP-A to the “High” state. The maximum voltage between the source and the drain of the transistor TP-D at this time is “γ”. In the transistor TP-A, the source voltage is “5 volts-γ” at time t1, increases to “5 volts-γ” at time t2, and finally recovers to 5 volts. The gate voltage also changes to “High” level. The transistor TP-A is thereby turned off. Through the above-described sequence of steps, the level shift circuit shown in FIG. 1 transmits the value of the low-voltage-amplitude input signal IN to obtain a high-voltage amplitude as output signal OUT.

As described above, the current mirror circuit CM1 formed by the transistors TP-C and TP-D is added on the source side of the p-channel transistors in the level shift circuit as shown in FIG. 1 to limit the amounts of current flowing as source-drain currents in the p-channel transistors TP-A and TP-B and to reduce the substantial source voltages according to the amounts of current, thus improving the operating speed of the circuit and reducing the power consumption.

### Embodiment 2

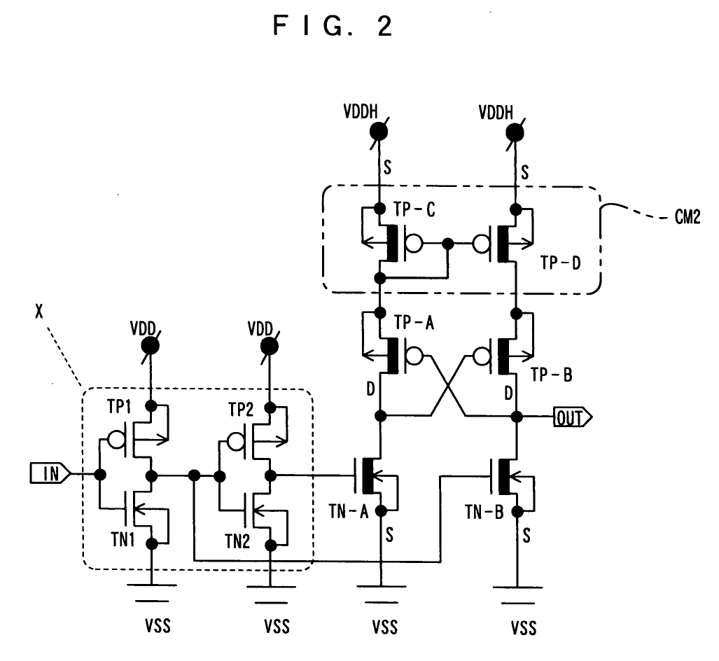

FIGS. 2, 7, and 8 show a level shift circuit (Embodiment 2) of the present invention.

FIG. 2 shows the level shift circuit (Embodiment 2). While the gates of the transistors TP-C and TP-D constituting the current mirror circuit CM1 in Embodiment 1 shown in FIG. 1 are connected to the drain of the transistor TP-D, the gates of the transistors TP-C and TP-D in a current mirror circuit CM2 corresponding to the current mirror circuit CM1 in Embodiment 1 are connected to the drain of the transistor TP-C. In other respects, the configuration shown in FIG. 2 is the same as that shown in FIG. 1.

The operation of the level shift circuit thus arranged will be described below.

While the level shift circuit shown in FIG. 1 operates as shown in FIGS. 5 and 6, the level shift circuit shown in FIG. 2 operates as shown in FIGS. 7 and 8.

An example of the operation in which a low-voltage amplitude between 0 volt and 1.8 volts (=VDD) applied as input signal IN is transmitted as a high-voltage amplitude between 0 volt and 5 volts (=VDDH) to be obtained as output signal OUT will be described.

A state in which the input signal IN is stable at 0-volt “Low” will first be considered. In this state, the gate of the transistor TN-A is in the off state and the gate of the transistor TN-B is in the on state. Accordingly, 0-volt “Low” is output as the output signal OUT. At this time, the gate of the transistor TP-A is in the on state and the gate of the transistor TP-B is in the off state. In this state, therefore, no direct tunneling current from 5 volts to 0 volt flows. The operation of the transistors TP-C and TP-D is maintained in a stable condition in a saturated region since no currents flow through the transistors TP-A and TP-B to which the drains of the transistors TP-C and TP-D are connected. A voltage of 5 volts appears on the sources and drains of the transistors TP-C and TP-D. Since the voltages on the sources and drains of the transistors TP-C and TP-D are equal to each other, the voltage between 0 volt and 5 volts is not divided by the transistors TP-C and TP-D, and the voltages on the sources of the transistors TP-A and TP-B are 5 volts.

A state immediately after change of the input signal IN from “Low” level to 1.8-volt “High” level will next be considered.

Through the inverter circuit X in the low-voltage operation region, 1.8-volt “High” level and 0-volt “Low” level of the input signal IN are applied to the gate of the transistor TN-A and the gate of the transistor TN-B, respectively. At this time, the gate of the transistor TP-A is in the on state while the gate of the transistor TP-B is in the off state. At this instant, the gates of the transistors TN-A and TP-A are in the on state and the section from the source of the transistor TN-A at 0 volt to the source of the transistor TP-C at 5 volts is in the on state, so that a direct tunneling current flows.

FIG. 7 shows variations in voltage and current with respect to time at the drain of the transistor TP-C at the instant when the value of the input signal IN changes from “Low” to “High”.

This instant is shown as t3. The transistors TP-C and TP-D operate in the saturated region at all times and a current is thereby caused to flow between the source and the drain. However, since mirroring is from the transistor TP-C in contrast with mirroring in the circuit shown in FIG. 1, the same value as the value of the current therein is only taken for the value of the current flowing between the source and the drain of the transistor TP-D, and a direct tunneling current is not caused to flow as a current larger than the mirrored current value. A voltage difference “a” proportional to the direct tunneling current is produced between the source and the drain of the transistor TP-C, and the value of “α” is smaller than that of “α” in Embodiment 1. Accordingly, the voltage on the wiring connecting the drain of the transistor TP-C and the source of the transistor TP-A is reduced to a value “VDDH-α”. The state of the gate of the transistor TP-A is thereby made variable.

FIG. 8 shows variations in voltage and current with respect to time at the drain of the transistor TP-D.

The corresponding instance on time axis in FIG. 8 is the same as that in FIG. 7 and is therefore shown as t3. The value of the current flowing from the source of the transistor TP-D and passing through the drain of the transistor TP-B is not proportional to the state of the gate of the transistor TP-B but made equal to the amount of current flowing between the source and the drain of the transistor TP-C by the current mirror effect. Since the gate of the transistor TP-B is also connected to the drain of the transistor TN-A, the state of the gate of the transistor TP-B changes to the “Low” state. Therefore, the current caused by the current mirror effect is larger than the amount of current caused by the voltage difference between the source and the drain.

Consequently, the source voltage is 5 volts and the drain voltage is “5 volts-α” in the transistor TP-C at the instant t3 immediately after the transition of the value of the input signal IN from “Low” to “High”, and the source voltage is 5 volts and the drain voltage is “5 volts-β” in the transistor TP-D at this instant, as shown in FIGS. 7 and 8. At this time, the same amounts of current flowing as source-drain currents in the transistors TP-C and TP-D are substantially the same as those in the circuit shown in FIG. 1, since the amount of current flowing between the source and the drain of the transistor TP-C is reflected in the value of the current between the source and the drain of the transistor TP-D by the current mirror effect.

The above-described operation will be considered from the transistor TP-A/TP-B side. In the transistor TP-A, at the time of transition from the on state to the off state, the source voltage decreases from 5 volts to “5 volts-α” and the gate voltage changes gradually to “5 volts-β” under the influence of the drain voltage of the transistor TP-B. Simultaneously, in the transistor TP-B, at the time of transition from the off state to the on state, the source voltage decreases from 5 volts to “5 volts-β” and the gate voltage changes to 0 volt. At this point in time, therefore, the transistor TP-B is substantially in the on state.

In comparison with FIGS. 5 and 6, no significant differences in amount of current are recognized at time t3, but the source-drain voltage differences produced in the transistors TP-C and TP-D are smaller than those in the circuit shown in FIG. 1.

The operation from the state in which both the transistors TP-A and TP-B are in the on state to settlement of a 5-volt “High” output obtained as the output signal OUT will next be considered.

The values of the current and voltage at the drains of the transistors TP-C and TP-D at this instant correspond to the states at time t4 shown in FIGS. 7 and 8.

In the transistor TP-A, the voltage on the drain of the transistor TP-A becomes “Low” when the voltage on the gate of the transistor TP-B connected by the common wiring becomes substantially “Low”. At this stage, source-drain currents flow in the transistors TP-A and TP-C but the gates are in the “High” state. Therefore the current values decrease. If the voltage difference between the source and the drain of the transistor TP-C at time t4 is “γ”, the voltage difference converges to 0 volt from “α” via γ in proportion to the reduction in the current value (α>γ).

Since the drain of the transistor TP-B is connected to the output signal OUT and to the gate of the transistor TP-A, a current flows between the source and the drain when the transistor TP-B becomes completely on. However, the value of this current is made substantially equal to the value of the current between the source and the drain of the transistor TP-C by the current mirror effect.

If the voltage difference between the source of the transistor TP-D and the drain of the transistor TP-D and the source of the transistor TP-B is “λ”, the voltage on the source of the transistor TP-B from time t3 to t4 changes from “VDDH-β” to “VDDH-λ” by being pulled to the output terminal OUT 0-volt side since the gate of the transistor TP-B is almost in the on state. The voltage difference “λ” is larger than the voltage difference “β” (β<λ).

The above-described operation will be considered from the transistor TP-A/TP-B side. The transistor TP-B is stable in the on state and, therefore, a current flows between the source and the drain before transition of the output signal OUT and the gate of the transistor TP-A to the “High” state.

In the transistor TP-A, the source voltage is “5 volts-α” at time t3, increases to “5 volts-γ” at time t4, and finally recovers to 5 volts. The gate voltage also changes to “High” level. The transistor TP-A is thereby turned off. Through the above-described sequence of steps, the level shift circuit shown in FIG. 2 transmits the value of the low-voltage-amplitude input signal IN to obtain a high-voltage amplitude as output signal OUT.

As described above, the current mirror circuit CM2 formed by the transistors TP-C and TP-D is added on the source side of the p-channel transistors in the level shift circuit as shown in FIG. 2 to limit the amounts of current flowing as source-drain currents in the p-channel transistors TP-A and TP-B and to reduce the substantial source voltages according to the amounts of current, thus improving the operating speed of the circuit and reducing the power consumption.

In the level shift circuit shown in FIG. 2, the values of substantial reductions in the voltages on the sources of the transistors TP-A and TP-B are low, as described above. Therefore, the level shift circuit shown in FIG. 2 cannot easily operate normally with respect to high frequencies in comparison with the circuit shown in FIG. 1. However, there is a possibility of the power supply becoming unstable if the source voltage is reduced. It is therefore thought that use of the level shift circuit shown in FIG. 2 is effective in improving the stability of the power supply if the operating speed is not extremely high. The stabilizing effect is particularly high in a case where several ten to several hundred level shift circuits are used in a power supply system LSI or the like.

### Embodiment 3

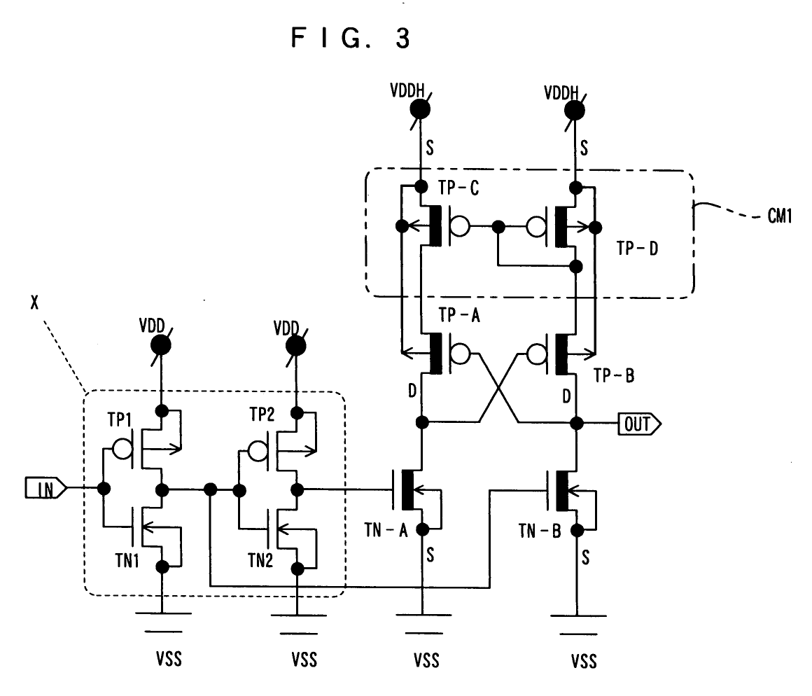

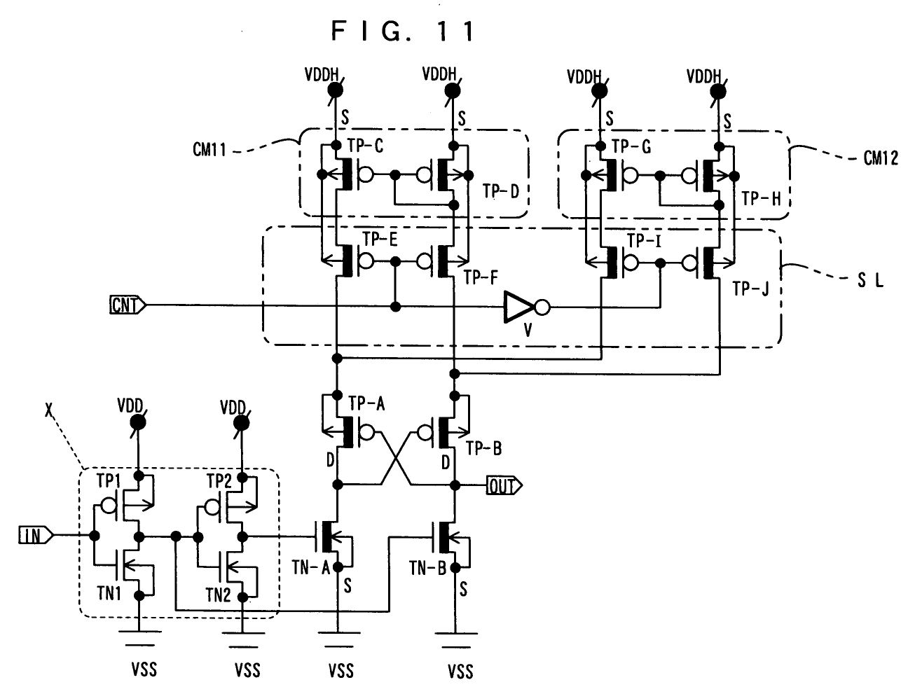

FIGS. 3 and 10 show Embodiment 3 of the present invention.

FIG. 3 shows a level shift circuit in Embodiment 3. While in Embodiment 1 shown in FIG. 1 the substrate voltage of the transistor TP-A is connected to the source of the transistor TP-A and the substrate voltage of the transistor TP-B is connected to the source of the transistor TP-B, Embodiment 3 is modified so that the substrate voltages of the transistors TP-A and TP-B are given from the third power supply voltage VDDH. In other respects, the configuration shown in FIG. 3 is the same as that shown in FIG. 1.

The operation of each transistor is substantially the same as the operation of the corresponding transistor in the circuit shown in FIG. 1. In implementation of these circuits on a semiconductor, the well structure of the level shift circuit in the configuration shown in FIG. 1 or 2 and the well structure of the level shift circuit in the configuration shown in FIG. 3 differ from each other.

In the case of the level shift circuit shown in FIG. 1 or 2, there is a need to provide separate wells for the transistors TP-A and TP-C as shown in FIG. 9 since the transistors TP-A and TP-C have different substrate voltages, although the transistors TP-A and TP-C are of the p-channel type, i.e., identical in channel type. In contrast, in the case of the configuration shown in FIG. 3, the transistors TP-A, TP-B, TP-C, and TP-D have a common substrate voltage, so that these transistors can be placed in one well and the mount area can be reduced.

### Embodiment 4

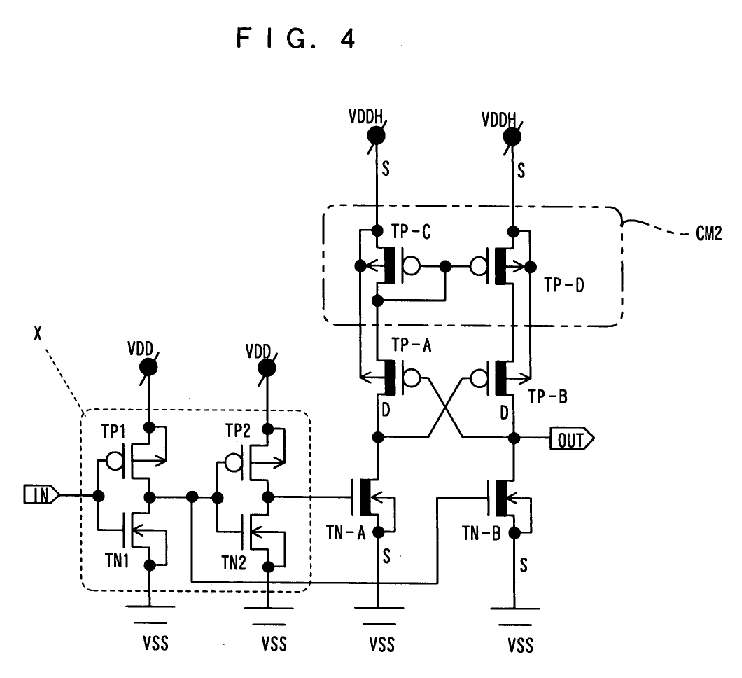

FIG. 4 shows a level shift circuit in Embodiment 4 of the present invention.

While in Embodiment 3 shown in FIG. 3 the gates of the transistors TP-C and TP-D constituting the current mirror circuit CM1 are connected to the drain of the transistor TP-D, the gates of the transistors TP-C and TP-D are connected to the drain of the transistor TP-C in Embodiment 4, as are those in the current mirror circuit CM2 in Embodiment 2 shown in FIG. 2. In other respects, the configuration shown in FIG. 4 is the same as that shown in FIG. 3. The operation of each transistor in the circuit shown in FIG. 4 is substantially the same as the operation of the corresponding transistor in the circuit shown in FIG. 2.

### Embodiment 5

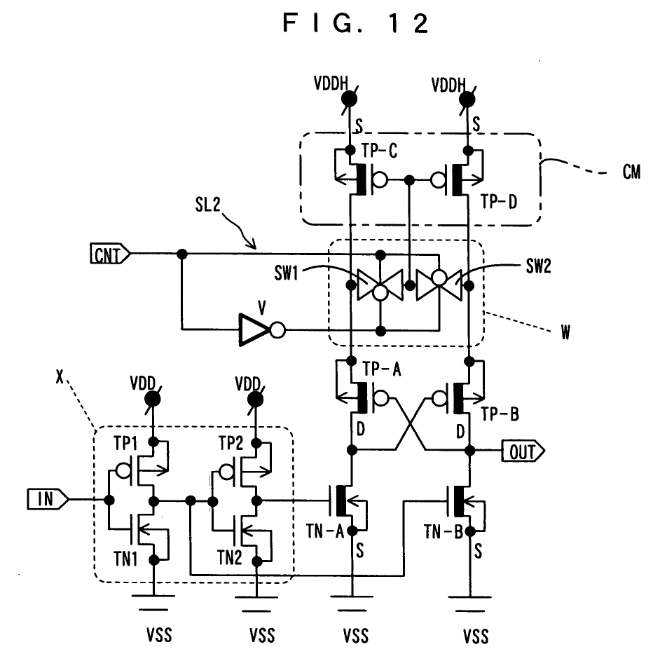

FIG. 11 shows a level shift circuit in Embodiment 5 of the present invention.

Referring to FIG. 11, current mirror circuits CM11 and CM12 are provided in parallel with each other between the sources of the above-described third and fourth MOS transistors TP-A and TP-B and the third power supply voltage VDDH.

The current mirror circuits CM11 and CM12 are identical in configuration to each other. The current mirror circuit CM11 is constituted by a fifth MOS transistor TP-C and a sixth MOS transistor TP-D. The current mirror circuit CM12 is constituted by a fifth MOS transistor TP-G and a sixth MOS transistor TP-H. Each of the transistors TP-C, TP-D, TP-G, and TP-H is of the p-channel conduction type.

A selecting circuit SL having a pair of seventh and eighth MOS transistors TP-E and TP-F having their gates connected to each other and another pair of seventh and eighth MOS transistors TP-I and TP-J having their gates connected to each other is provided between the current mirror circuits CM11 and CM12 and the sources of the third and fourth MOS transistors TP-A and TP-B. The selecting circuit SL is arranged to select one of the current mirror circuits CM11 and CM12 according to a control input CNT. Each of the transistors TP-E, TP-F, TP-I, and TP-J is of the p-conduction type. In other respects, the configuration shown in FIG. 11 is the same as that in Embodiment 1.

The current mirror circuit CM11 formed by the transistors TP-C and TP-D differs in size from the current mirror circuit CM12 formed by the transistors TP-G and TP-H. While an example of the current mirror circuits CM11 and CM12 each having the same configuration as that of the current mirror circuit CM1 shown in FIG. 1 has been described, the arrangement may alternatively be such that the current mirror circuits CM11 and CM12 are formed in different configurations and one of the current mirror circuits CM11 and CM12 is selected. More specifically, the current mirror circuit CM2 shown in FIG. 2 may be substituted for the current mirror circuit CM12 and an optimum characteristic may be selected from the two current mirror circuits according to circumstances.

### Embodiment 6

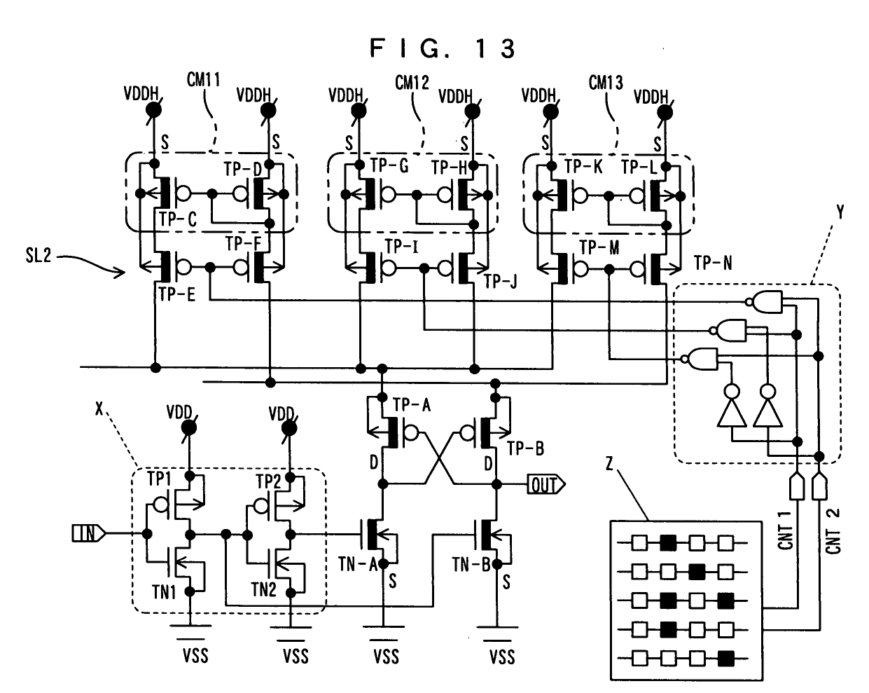

FIG. 12 shows a level shift circuit in Embodiment 6 of the present invention.

Referring to FIG. 12, transistors TP-C and TP-D constituting a current mirror circuit, a first switch circuit SW1 for connection/disconnection between the drain of the transistor TP-C and a point of connection between the gates of the transistors TP-C and TP-D and a second switch circuit SW2 for connection/disconnection between the drain of the transistor TP-D and a point of connection between the gates of the transistors TP-C and TP-D are provided between the sources of the transistors TP-A and TP-B and the third power supply voltage VDDH, and a selecting circuit is arranged to set one of the first and second switch circuits SW1 and SW2 in the connecting state according to a control input CNT. Each of the transistors TP-C and TP-D is of the p-conduction type. A reference character W denotes a transfer gate having the first and second switches SW1 and SW2. Each of an inverter V and the transfer gate W is constituted by high-voltage MOS transistors.

As described above, the transfer gate W is provided in wiring lines connecting the drains of the transistors TP-C and TP-D and the gates of these transistors for the current mirror circuit formed by the transistors TP-C and TP-D and is connected to a current mirror circuit control terminal, thereby enabling selection from the circuits shown in FIGS. 1 and 2 or from the circuits shown in FIGS. 3 and 4 while using a comparatively small number of transistors. In this way, an optimum characteristic can be selected from the two current mirror circuits according to circumstances.

### Embodiment 7

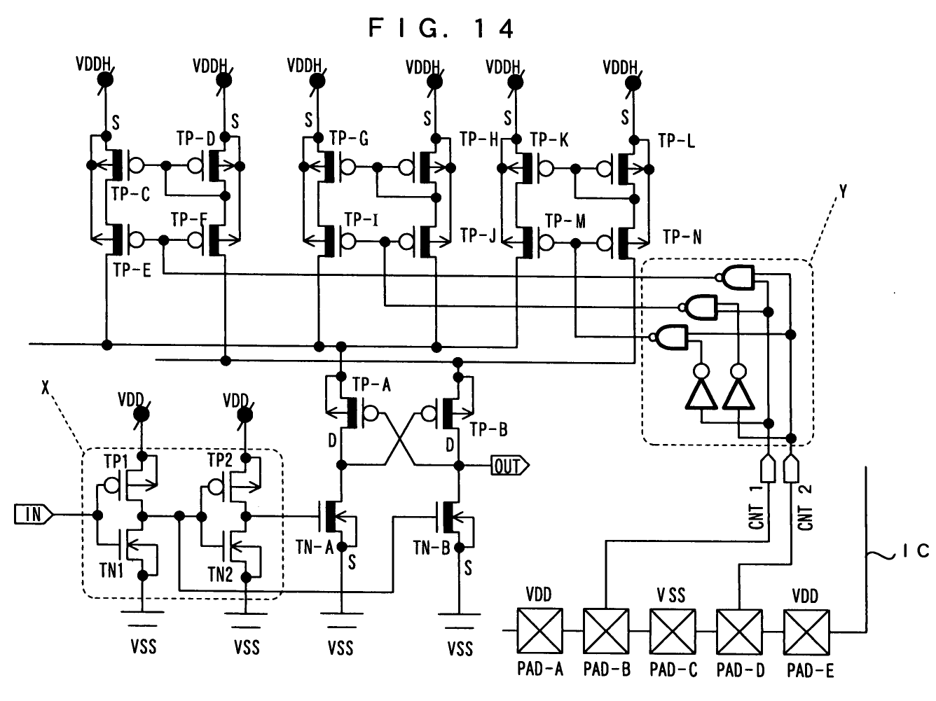

FIG. 13 shows a level shift circuit in Embodiment 7 of the present invention.

While in Embodiment 5 shown in FIG. 11 two current mirror circuits CM11 and CM12 are provided between the sources of the above-described third and fourth MOS transistors TP-A and TP-B and the third power supply voltage VDDH, three current mirror circuits CM11, CM12, and CM13 are provided in parallel with each other in the arrangement shown in FIG. 13. The current mirror circuit CM11 is constituted by transistors TP-C and TP-D; the current mirror circuit CM12 by transistors TP-G and TP-H; and the current mirror circuit CM13 by transistors TP-K and TP-L. Each of these transistors is of the p-conduction type.

A selecting circuit SL having a first pair of seventh and eighth MOS transistors TP-E and TP-F having their gates connected to each other, a second pair of seventh and eighth MOS transistors TP-I and TP-J having their gates connected to each other and a third pair of seventh and eighth MOS transistors TP-M and TP-N having their gates connected to each other is provided between the current mirror circuits CM11, CM12, and CM13 and the sources of the third and fourth MOS transistors TP-A and TP-B. The selecting circuit SL for selecting one of the current mirror circuits CM11, CM12, and CM13 is controlled by an arrangement described below.

Reference characters CNT1 denote a first-bit terminal in multibit current mirror circuit control terminals; Reference characters CNT2 denote a second-bit terminal in the multibit current mirror circuit control terminals; a reference character Z denotes an internal memory which is provided as information storage, and in which signals to be supplied to the current mirror circuit control input terminals are stored; and a reference character Y denotes a logic region which is constituted by high-voltage MOS transistors, and which selects one of the current mirror circuits as required according to the signals supplied to the multibit current mirror circuit control input terminals. In other respects, the configuration is the same as that in Embodiment 5.

As shown in FIG. 13, multibit current mirror circuit control terminals are provided in the circuit shown in FIG. 11 to increase the number of selectable current mirror circuits from 2 to three or more. An input to the multibit current mirror circuit control terminals is given from the internal memory to change the characteristics of the current mirror circuit according to circumstances. The internal memory may be a non-rewritable nonvolatile memory, a rewritable nonvolatile memory or a register.

A storage place in the rewritable nonvolatile memory in which necessary information is stored may be freely selected from, for example, an ordinary program storage region, a redundant storage region, an identification (ID) code setting region and a testing storage region in the rewritable nonvolatile memory.

### Embodiment 8

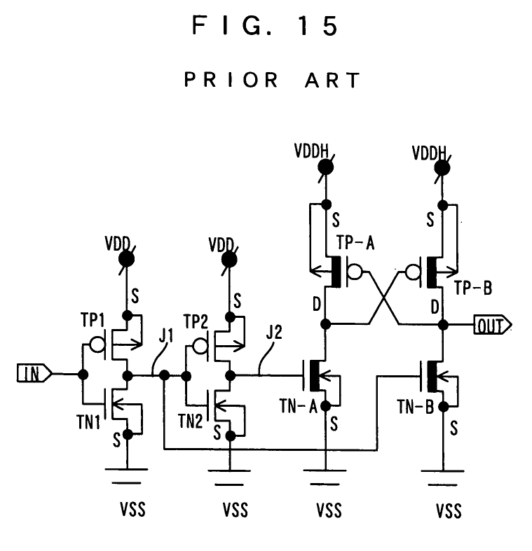

FIG. 14 shows a level shift circuit in Embodiment 8 of the present invention.

While the selecting circuit SL2 is controlled through the logic region Y by using the internal memory Z in the circuit shown in FIG. 13, the circuit shown in FIG. 14 is arranged so that the current mirror circuit control terminals in an semiconductor integrated circuit device IC incorporating the level shift circuit can be controlled from the outside.

On opposite sides of a pad PAD-B which is an external terminal connected to the first-bit terminal CNT1 in the current mirror circuit control terminals, a pad PAD-A connected to VDD and a pad PAD-C connected to VSS are placed. On opposite sides of a pad PAD-D connected to the second-bit terminal CNT2 in the current mirror circuit control terminals, a pad PAD-E connected to VDD and the pad PAD-C connected to VSS are placed.

In the level shift circuit configured as described above, wiring to any of the adjacent power supply pads may be performed after testing by considering variations in the entire semiconductor integrated circuit and Vth characteristics. In this way, adjustment can be performed by considering the electrical characteristics of the entire integrated circuit after testing.

In each of the above-described embodiments, the P-channel MOS transistors may be replaced with N-channel transistors. In such a case, transistor size adjustment may be performed to obtain the same characteristics as those described above.

The level shift circuit in accordance with the present invention is capable of reducing the power consumption and effectively improving the operating speed while slightly increasing the circuit area in comparison with the conventional circuit, and is, therefore, useful in a system LSI core or an analog LSI core having a multiple-power-supply configuration.

What is claimed is:

1. A level shift circuit in which an input signal having a first voltage difference is converted into an output signal having a second voltage difference larger than the first voltage difference, the level shift circuit comprising:
a first MOS transistor having a first type of conductivity, the input signal being supplied to the gate of the first MOS transistor, a low-voltage-side reference voltage of the output signal being supplied to the source of the first MOS transistor;
a second MOS transistor having the first type of conductivity, an inverted signal obtained by inverting the input signal being supplied to the gate of the second MOS transistor, the low-voltage-side reference voltage being supplied to the source of the second MOS transistor;
a third MOS transistor having a second type of conductivity, having its drain connected to the drain of the first MOS transistor and having its gate connected to the drain of the second MOS transistor;
a fourth MOS transistor having the second type of conductivity, having its drain connected to the drain of the second MOS transistor and having its gate connected to the drain of the first MOS transistor; and
a fifth MOS transistor and a sixth MOS transistor provided between the sources of the third and fourth MOS transistors and nodes to which a high-voltage-side reference voltage having the second voltage difference from the low-voltage-side reference voltage is supplied, the fifth and sixth MOS transistors constituting a current mirror circuit, each of the fifth and sixth MOS transistors having the second type of conductivity, wherein
the output signal is output from a point of connection between the drain of the second MOS transistor and the drain of the fourth MOS transistor.

2. The level shift circuit according to claim 1, wherein the gate of the fifth MOS transistor and the gate of the sixth MOS transistor are connected to the drain of the sixth MOS transistor.

3. The level shift circuit according to claim 1, wherein the gate of the fifth MOS transistor and the gate of the sixth MOS transistor are connected to the drain of the fifth MOS transistor.

4. The level shift circuit according to claim 2, wherein a voltage equal to a voltage on a point of connection between the third MOS transistor and the fifth MOS transistor is supplied to the substrate of the third MOS transistor, and a voltage equal to a voltage on a point of connection between the fourth MOS transistor and the sixth MOS transistor is supplied to the substrate of the fourth MOS transistor.

5. The level shift circuit according to claim 3, wherein a voltage equal to a voltage on a point of connection between the third MOS transistor and the fifth MOS transistor is supplied to the substrate of the third MOS transistor, and a voltage equal to a voltage on a point of connection between the fourth MOS transistor and the sixth MOS transistor is supplied to the substrate of the fourth MOS transistor.

6. The level shift circuit according to claim 2, wherein the substrate voltage of the third MOS transistor is equal to the substrate voltage of the fifth MOS transistor, and the substrate voltage of the fourth MOS transistor is equal to the substrate voltage of the sixth MOS transistor.

7. The level shift circuit according to claim 3, wherein the substrate voltage of the third MOS transistor is equal to the substrate voltage of the fifth MOS transistor, and the substrate voltage of the fourth MOS transistor is equal to the substrate voltage of the sixth MOS transistor.

8. A level shift circuit in which an input signal having a first voltage difference is converted into an output signal having a second voltage difference larger than the first voltage difference, the level shift circuit comprising:
a first MOS transistor having a first type of conductivity, the input signal being supplied to the gate of the first MOS transistor, a low-voltage-side reference voltage of the output signal being supplied to the source of the first MOS transistor;
a second MOS transistor having the first type of conductivity, an inverted signal obtained by inverting the input signal being supplied to the gate of the second MOS transistor, the low-voltage-side reference voltage being supplied to the source of the second MOS transistor;
a third MOS transistor having a second type of conductivity, having its drain connected to the drain of the first MOS transistor and having its gate connected to the drain of the second MOS transistor;
a fourth MOS transistor having the second type of conductivity, having its drain connected to the drain of the second MOS transistor and having its gate connected to the drain of the first MOS transistor;
a plurality of current mirror circuits provided between the sources of the third and fourth MOS transistors and nodes to which a high-voltage-side reference voltage having the second voltage difference from the low-voltage-side reference voltage is supplied; and
a selector which selects, according to a control input, one of the plurality of current mirror circuits to have effective connections to the sources of the third and fourth MOS transistors, wherein
the output signal is output from a point of connection between the drain of the second MOS transistor and the drain of the fourth MOS transistor.

9. The level shift circuit according to claim 8, wherein each of the plurality of current mirror circuits includes fifth and sixth MOS transistors having the second type of conductivity, the gate of the fifth MOS transistor and the gate of the sixth MOS transistor being connected to the drain of the fifth MOS transistor or the drain of the sixth MOS transistor.

10. The level shift circuit according to claim 9, further comprising pairs of seventh and eighth MOS transistors provided between the plurality of current mirror circuits and the sources of the third and fourth MOS transistors, the gates of each pair of seventh and eight MOS transistors being connected to each other, each of the seventh and eight MOS transistors having the second type of conductivity, wherein
the selecting circuit selects according to the control input one of the plurality of current mirror circuits to be used by outputting, to a node to which the gates of the seventh and eight MOS transistors are connected in common, a selecting signal by which the corresponding seventh and eight MOS transistors are made conductive.

11. A level shift circuit in which an input signal having a first voltage difference is converted into an output signal having a second voltage difference larger than the first voltage difference, the level shift circuit comprising:
a first MOS transistor having a first type of conductivity, the input signal being supplied to the gate of the first MOS transistor, a low-voltage-side reference voltage of the output signal being supplied to the source of the first MOS transistor;
a second MOS transistor having the first type of conductivity, an inverted signal obtained by inverting the input signal being supplied to the gate of the second MOS transistor, the low-voltage-side reference voltage being supplied to the source of the second MOS transistor;
a third MOS transistor having a second type of conductivity, having its drain connected to the drain of the first MOS transistor and having its gate connected to the drain of the second MOS transistor;
a fourth MOS transistor having the second type of conductivity, having its drain connected to the drain of the second MOS transistor and having its gate connected to the drain of the first MOS transistor;
fifth and sixth MOS transistors provided between the sources of the third and fourth MOS transistors and nodes to which a high-voltage-side reference voltage having the second voltage difference from the low-voltage-side reference voltage is supplied, the fifth and sixth MOS transistors constituting a current mirror circuit, each of the fifth and sixth MOS transistors having the second type of conductivity;
a first switch circuit which establishes or cancels a connection between the drain of the fifth MOS transistor and a point of connection between the gate of the fifth MOS transistor and the gate of the sixth MOS transistor;
a second switch circuit which establishes or cancels a connection between the drain of the sixth MOS transistor and a point of connection between the gate of the fifth MOS transistor and the gate of the sixth MOS transistor; and
a selecting circuit which selects according to a control input one of the first switch circuit and the second switch circuit so that the first or second switch circuit is set in a connecting state, wherein
the output signal is output from a point of connection between the drain of the second MOS transistor and the drain of the fourth MOS transistor.

12. The level shift circuit according to claim 1, wherein the first type of conductivity is the n-channel type while the second type of conductivity is the p-channel type.

13. The level shift circuit according to claim 8, wherein the first type of conductivity is the n-channel type while the second type of conductivity is the p-channel type.

14. The level shift circuit according to claim 11, wherein the first type of conductivity is the n-channel type while the second type of conductivity is the p-channel type.

15. A semiconductor integrated circuit device in which the level shift circuit according to claim 8 is mounted.

16. The semiconductor integrated circuit device according to claim 15, wherein selection of one of the plurality of current mirror circuits by the selector is performed according to a control input designated through an external terminal.

17. The semiconductor integrated circuit device according to claim 15, wherein the selector includes an information storage constituted by a memory or a register, and a selecting circuit which selects, according to an output from the information storage, one of the plurality of current mirror circuits to be used.

18. The semiconductor integrated circuit device according to claim 17, wherein the information storage comprises a non-rewritable nonvolatile memory.

19. The semiconductor integrated circuit device according to claim 17, wherein the information storage comprises a rewritable nonvolatile memory.

20. The semiconductor integrated circuit device according to claim 19, wherein information in the rewritable nonvolatile memory is stored in an ordinary program storage region in the rewritable nonvolatile memory.

21. The semiconductor integrated circuit device according to claim 19, wherein information in the rewritable nonvolatile memory is stored in a redundant storage region in the rewritable nonvolatile memory.

22. The semiconductor integrated circuit device according to claim 19, wherein information in the rewritable nonvolatile memory is stored in an ID code setting region in the rewritable nonvolatile memory.

23. The semiconductor integrated circuit device according to claim 19, wherein information in the rewritable nonvolatile memory is stored in a testing storage region in the rewritable nonvolatile memory.
